(19) United States
(12) Patent Application Publication
(10) Pub. No.: US 2025/0183234 A1
(43) Pub. Date: Jun. 5, 2025

(54) SINGLE COMPLEMENTARY METAL-OXIDE SEMICONDUCTOR BACKPLANE TO SUPPORT MULTIPLE LIGHT EMITTING DIODE PIXEL SIZES

(71) Applicant: Lumileds LLC, San Jose, CA (US)

(72) Inventors: Ronald Johannes BONNE, Plainfield, IL (US); Norbert Alois LESCH, Vaals (NL)

(73) Assignee: Lumileds LLC, San Jose, CA (US)

(21) Appl. No.: 18/524,599

(22) Filed: Nov. 30, 2023

(51) Int. Cl. H01L 25/075; H01L 25/16; H01L 33/62

(52) U.S. Cl. CPC H01L 25/0753; H01L 25/167; H10H 20/857

(57) ABSTRACT

According to one or more embodiments, a device is provided. The device includes a complementary metal oxide semiconductor (CMOS) backplane comprising multiple light emitting diode (LED) pixels areas. The device includes a pixel drivers inside the CMOS backplane. Each pixel driver of the pixel drivers is coupled to a ground. The pixel drivers are configured into groups corresponding to the multiple LED pixels areas.

### BACKGROUND

Conventional technologies for designing, manufacturing, and implementing a complementary metal-oxide semiconductor (CMOS) backplane for hybridizing pixelated light emitting diode (LED) arrays typically cost an order of magnitude higher than a cost of redefining a segmentation and contact pattern of a monolithic micro-LED (μLED) pixel array. Thus, there is a need for designing multiple application-specific integrated circuit (ASIC) CMOS backplanes dependent on the μLED configuration that a specific application calls for. Conventional technologies currently do not provide a solution.

### SUMMARY

According to one or more embodiments, a device is provided. The device includes a complementary metal-oxide semiconductor (CMOS) backplane comprising multiple light emitting diode (LED) pixels areas. The device includes a plurality of pixel drivers inside the CMOS backplane, each pixel driver of the plurality of pixel drivers being coupled to a ground. The one or more pixel drivers are configured into one or more groups corresponding to the multiple LED pixels areas.

### BRIEF DESCRIPTION OF THE DRAWINGS

A more detailed understanding can be had from the following description, given by way of example in conjunction with the accompanying drawings wherein:

FIG. 1 depicts device according to one or more embodiments;

FIG. 3 a diagram of a device according to one or more embodiments;

FIG. 4 a diagram of a device according to one or more embodiments;

FIG. 5 a diagram of a device according to one or more embodiments;

FIG. 6 is a diagram of an example vehicle headlamp system; and

FIG. 7 is a diagram of another example vehicle headlamp system.

### DETAILED DESCRIPTION

Described herein is a single complementary metal-oxide semiconductor (CMOS) backplane that is configured to receive and connect with multiple light emitting diode (LED) pixel sizes. The CMOS backplane can be implemented in a CMOS, which further can be implemented in a device including the LEDS, each corresponding to one or more pixel sizes.

According to one or more embodiments, the CMOS backplane is configured to receive multiple LED pixel sizes with minimal to no change to a CMOS chip and/or only a change in software, firmware, or one-time programmable (OTP) memory in the CMOS. The CMOS backplane can include (and can be built/manufactured to include) one or more pixel drivers. The one or more pixel drivers can be interconnected in one or more groups (e.g., the plurality of pre-defined pixel driver groupings) to drive a single pixel.

According to one or more embodiments, the one or more groups can be implemented via a design of metal interconnect layers of the CMOS. A technical effect and benefit of the design of metal interconnect layers includes not redesigning (e.g., leaving the same) a base silicon of the CMOS and, therefore, little to no intervention at an application level of the CMOS and/or the device is required.

According to one or more embodiments, the one or more groups can be implemented via an n-layer interconnect design of an LED array to provide a plurality of connection points to individual drivers and combining one or more of the plurality of connection points to operate a single pixel. Further, the n-layer interconnect design can be coupled with a software or firmware configuration at an application level of the CMOS to operate the CMOS. A technical effect and benefit of the n-layer interconnect design include no additional cost to the CMOS backplane and downstream processing of the CMOS and/or the device. Applications of the CMOS backplane, the CMOS, and/or the device described herein include, but are not limited to, μLED pixel arrays and/or Mini-LED pixel arrays (e.g., with very high pixels per inch (PPI) that are directly hybridized on top of the CMOS backplane.

According to one or more embodiments, the one or more groups can be implemented via a hybrid configuration between the design of metal interconnect layers of the CMOS and the n-layer interconnect design of an LED array. The hybrid configuration can include configuring a top metal layer of the CMOS to be different for each different LED array and providing corresponding interconnect. Further, the hybrid configuration can be coupled with pre-programming the CMOS (e.g., using a fuse-able OTP memory to one of the plurality of pre-defined pixel driver groupings).

Examples of different light illumination systems and/or LED implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout. Further, LEDs may have a relatively large light emitting region with outer walls surrounded on at least one side by very thing reflectors, such as dichroic mirrors, which may enable very close spacing of the LEDs, such as described above, while still maintaining a contrast between neighboring LEDs. In some embodiments, the reflectors may only be placed in locations where the side wall is adjacent a side wall of a neighboring LED. For such LEDs, standard pick and place techniques may be difficult for the reasons described above, particularly as the close spacing makes any movement of the LEDs problematic for their functionality.

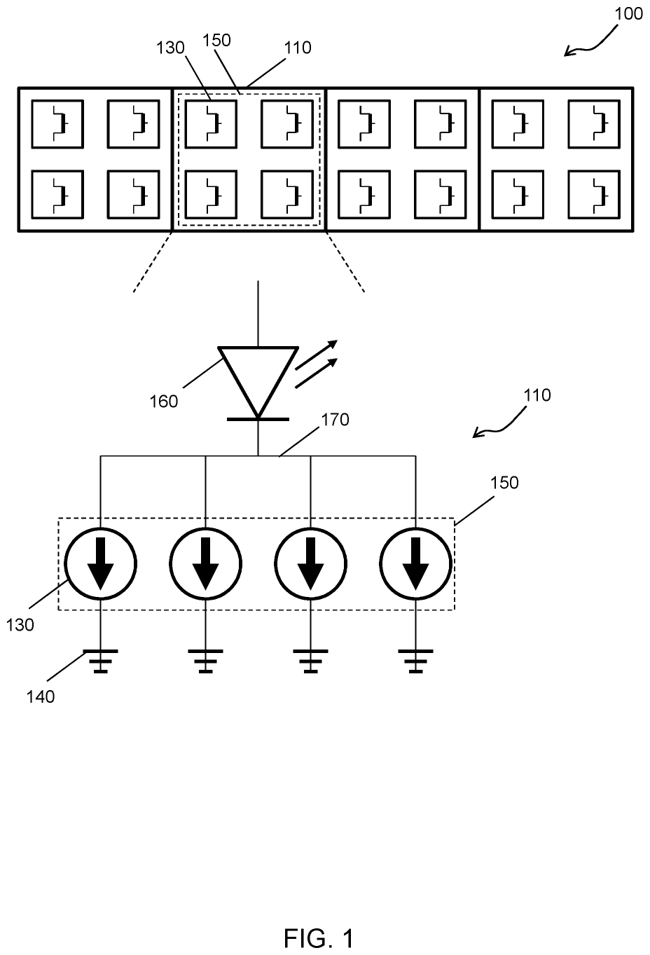

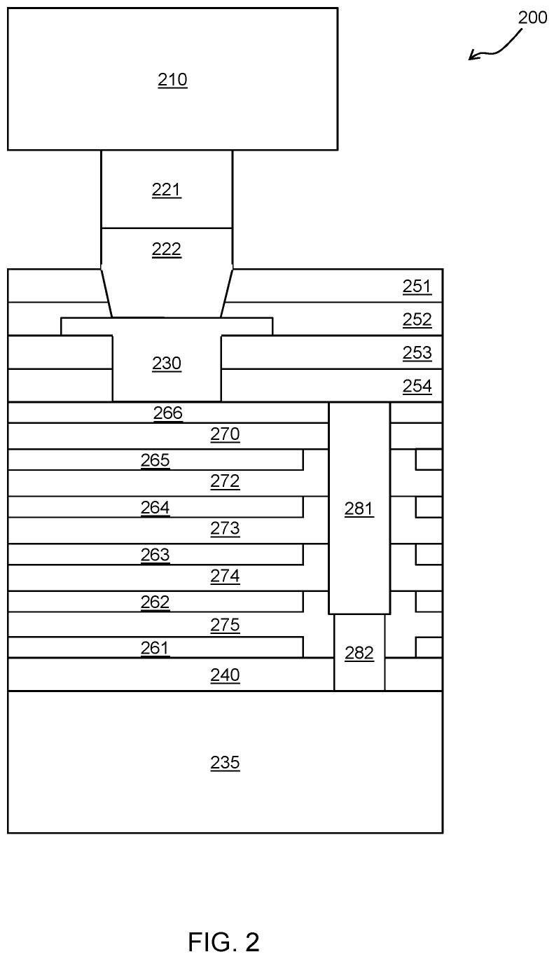

FIG. 1 shows a device 100 according to one or more embodiments. The device 100 includes multiple LED pixels areas (e.g., represented by a pixel 110). The device 100 can be representative of a CMOS backplane. One or more pixel drivers 130 sit inside the CMOS backplane, and each pixel driver 130 can be coupled to a ground 140. The one or more pixel drivers 130 can be design to be include in one or more groups (e.g., represented by a group 150). Any of the one or more groups can include one, two, three, four, five, six, seven, eight, or more drivers, etc. The groups of the one or more pixel drivers 130 can have a same number of pixel drivers 130 (e.g., each group can have two pixel drivers). The groups of the one or more pixel drivers 130 can have varying numbers of pixel drivers 130 (e.g., a first group can have two pixel drivers while a second group can have four pixel drivers).

As shown in the pixel 110 (e.g., with respect to each of the multiple LED pixels areas), the pixel 110 includes the one or more pixel drivers 130 that corresponds to a LED 160. Thus, the multiple LED pixels areas of the device 100 can correspond to and are configured to receive the multiple LEDs 160. According to one or more embodiments, and as shown in FIG. 1, the device 100 can include the four (4) pixel drivers 130 interconnected (via a configuration 170 as described herein) in the group 150 for the LED 160. By way of example, the device 100 is shown with sixteen (16) pixel drivers 130 interconnected into four (4) separate groups 150 to drive a corresponding pixel 110 (e.g., the plurality of pre-defined pixel driver groupings to drive a single pixel).

According to one or more embodiments, the configuration 170 can be a design of metal interconnect layers of the CMOS, an n-layer interconnect design of an LED array, and a hybrid configuration between the design of metal interconnect layers of the CMOS and the n-layer interconnect design of the LED array.

FIG. 2 IS a diagram of a device 200 according to one or more embodiments. The device 200 provides a design of metal interconnect layers of a CMOS layer stack. The device 200 includes an LED 210, a μBump 221/222 (e.g., respectively made of tin (Sn) and copper (Cu)), a contact 230, a silicon (Si) layer 235, a layer (e.g., phosphosilicate glass) 240. The μBump 221/222 is processed on top of the LED 210. The LED 210 is attached on top of the μBump 221/222. The LED 210 can be segmented into pixels, with one μBump per pixel forming a p-contact. The n-contact can be realized through a metallization of the LED segmentation to the edge of the die, then back into the CMOS with μBumps. According to one or more embodiments, the configuration 170 can leave a base silicon of a CMOS (e.g., silicon (Si) layer 235) the same (e.g., the driver circuits, their size and location, and controlling logic) and increase a size of a pixel of the LED 210 by a factor, for example, of four (4).

The device 200 includes one or more SiN/SiO2 layers 251, 252, 253, and 254. The device 200 includes one or more metal (e.g., Cu) layers 261, 262, 263, 264, 265, and 266. The device 200 includes a layer 270 (e.g., undoped silicate glass) and one or more layers (e.g., flourosilicate glass) 272, 273, 274, and 275. The device 200 includes one or more contacts 281 and 282. The one or more metal (e.g., Cu) layers 261, 262, 263, 264, 265, and 266 are metal interconnect layers that are configured according to embodiments herein.

The configuration 170 of the design of metal interconnect layers of the CMOS can be implemented within the device 120 through reconfiguring a metal layer stack. Accordingly, each metal layer stack can correspond to a unique stock keeping unit (SKU) for each individual implementation. In an embodiment, a full metal layer stack of the CMOS can be provided to group 150 the pixel drivers 130, which avoids changes in software, firmware, or OTP memory in the CMOS. In an embodiment, when only a top layer of the device 120 is modified to provide a “shorting” between the pixel drivers 130, software, firmware, or one-time programmable OTP memory in the CMOS can be provided to group 150 the pixel driver 130.

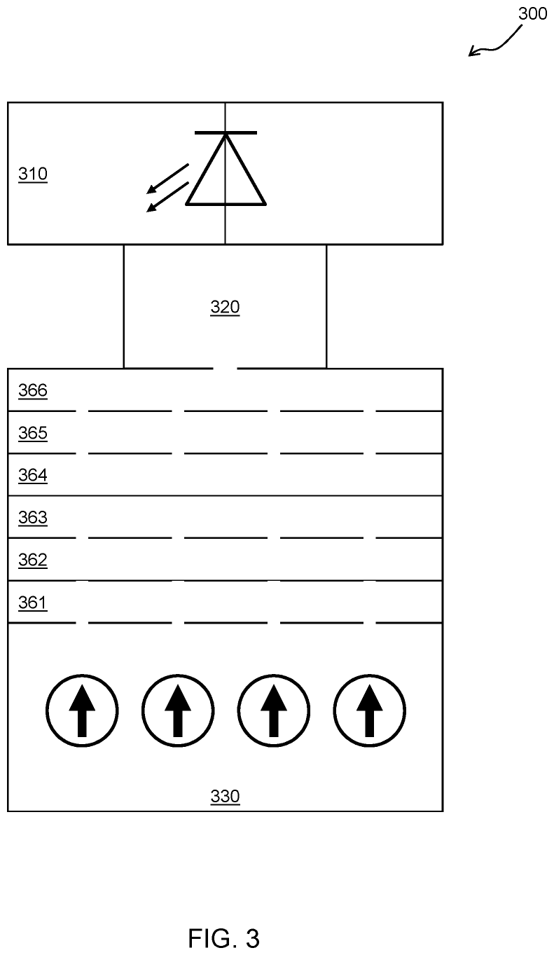

According to one or more embodiments, the configuration 170 cam electrically connect four (4) of the original drivers in parallel to drive the larger pixel. By way of example, to achieve the paralleling of four (4) drivers for a single pixel, the configuration 170 is shown with respect to FIGS. 3-5.

FIG. 3 a diagram of a device 300 (e.g., including a CMOS layer stack) according to one or more embodiments. The device 300 includes an LED 310, a contact 320 (e.g., a μBump), and a driver layer 330. The device 300 includes one or more interconnect layers 361, 362, 363, 364, 365, and 366 (e.g., the one or more metal (e.g., Cu) layers 261, 262, 263, 264, 265, and 266) configured according to altering the interconnect to fully match the LED 310 both on a driver side (e.g., interconnect layers 365 and 366) and a logic side (e.g., interconnect layers 361, 362, 363, and 364).

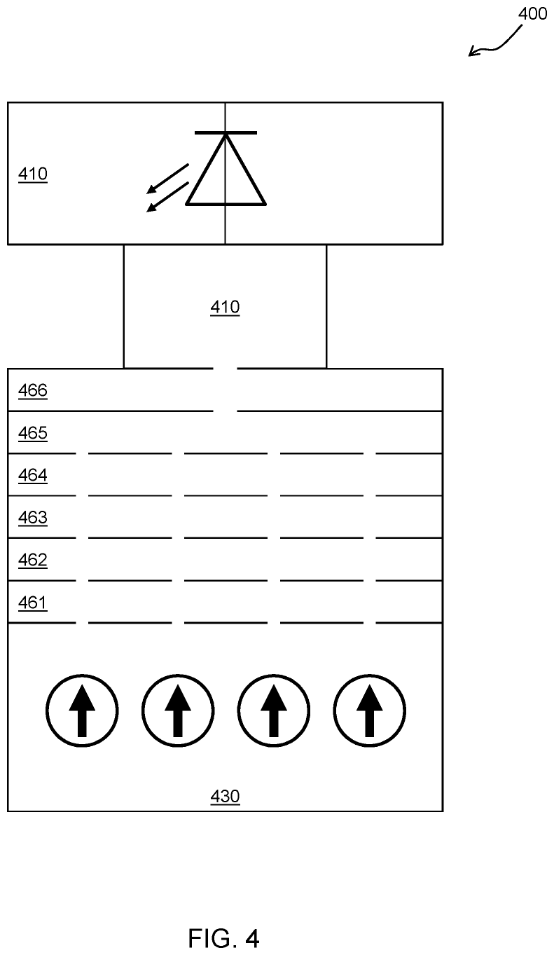

FIG. 4 a diagram of a device 400 (e.g., including a CMOS layer stack) according to one or more embodiments. The device 400 includes an LED 410, a contact 420 (e.g., a μBump), and a driver layer 430. The device 400 includes one or more interconnect layers 461, 462, 463, 464, 465, and 466 (e.g., the one or more metal (e.g., Cu) layers 261, 262, 263, 264, 265, and 266), where only the top layers 465 and 466 are configured (e.g., driver power distribution) to connect the contact 420 to the driver layer 430, while the logic side (e.g., interconnect layers 461, 462, 463, and 464) includes pass through connections. Note that additional programming of the CMOS can be implemented to drive the LED 410.

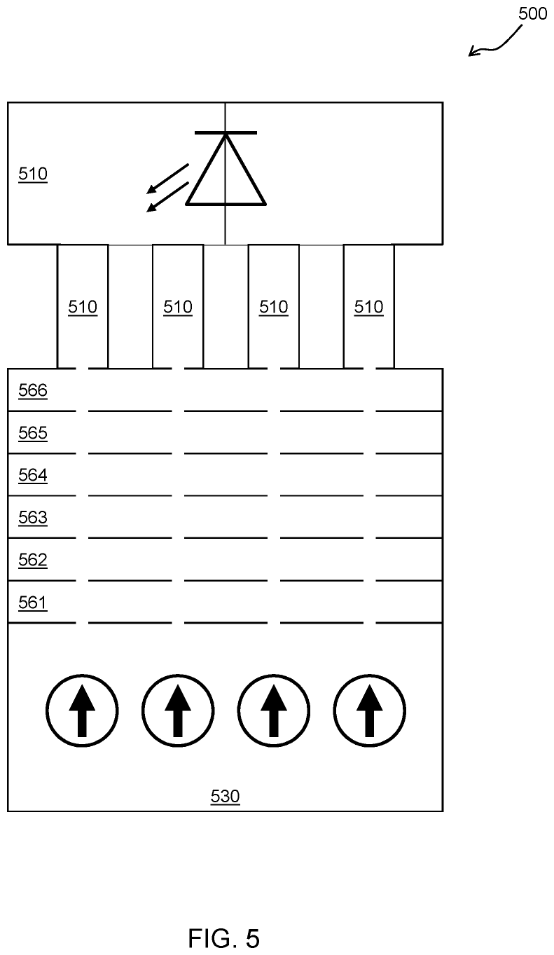

The configuration 170 of the n-layer interconnect design of an LED array can be implemented within a die of the LED 160 by providing multiple n-contacts for the pixel 110. FIG. 5 a diagram of a device 500 (e.g., including a CMOS layer stack) according to one or more embodiments. The device 500 includes an LED 510, one or more contacts 520 (e.g., μBumps), and a driver layer 530. The device 500 includes one or more interconnect layers 561, 562, 563, 564, 565, and 566 (e.g., the one or more metal (e.g., Cu) layers 261, 262, 263, 264, 265, and 266). The device 500 provides a solution whereby the CMOS and μBumps are used and paralleling of drivers of the driver layer 530 is perform on a p-metal side of the LED 510 (e.g., arrange the metallization of the LED 510 to match the CMOS). Accordingly to the device 500, no change in the CMOS is needed for any pixel configuration.

The configuration 170 of the hybrid configuration can be implemented with respect to the examples herein. According to one or more embodiments, the hybrid configuration can include an attachment of an LED pixel array to the CMOS backplane by micro-bumps (e.g., FIG. 2, μBump 221/222), gold bumps, direct attach or any other attachment method.

The configuration 170 (e.g., the grouping of pixel drivers) can be provided digitally through software, firmware, or OTP memory in the CMOS. By way of example, the firmware of the CMOS digitally combined individual drivers 130 to produce and route a combination of currents to the pixel 110 (e.g., a firmware of the CMOS digitally configure the one or more pixel drivers into the one or more groups to produce and route a combination of currents to corresponding to the multiple LED pixels areas). Note that while the device of FIG. 1 shows a anode configuration, the configuration 170 can include an n or p-layer so that the device 100 can work with a cathode configuration. A technical effect and benefit of the configuration 170 is to enable a combination of currents of any number of individual drivers 130 and route the combination of currents to the single pixel 110 to guarantee even load to the drivers 130 and even distribution to the pixel 110 (e.g., the configuration 170 is design accordingly in metallization layers on the CMOS or the LED 160.

Note that, conventionally, traditional chips are cost expensive because traditional chips include a high volume of individual small pixels (e.g., 20,000 individual small pixels) and corresponding drivers and LEDs (e.g., each driver requires a single LED that corresponds to each individual small pixel). In contrast, and as a technical effect and benefit, the device 100 from an electrical perspective combines the individual drivers 130 into the groups 150, where the drivers 130 of the group 150 operate together to drive the single large pixel 110 covering a greater surface area of the device 100 (e.g., instead of individual small pixels, the device provides 5,000 pixels across 20,000 drivers). Thus, the device addresses the need for designing multiple ASIC CMOS backplanes dependent on the μLED configuration that a specific application calls for.

Also, the technical effect and benefit of having multiple drivers 130 run a single pixel 110 increases an analog current granularity with which the pixel 110 can be driven, making hybrid dimming by the device 100 a lot easier than in the individual small pixels of the traditional chips (e.g., the single pixel-per-driver scenario). According to one or more embodiments, with respect to the CMOS backplane, the CMOS, and/or the device described herein, a direct current (DC) current of any individual pixel drivers 130 does not have to be identical. Further, any pulse width modulation (PWM) of the pixel drivers 130 in a group 150 operate synchronously between the pixel drivers 130. Thus, the pixel groupings 150 of the device 100 provide the technical effect and benefit of enabling simultaneous rising and falling edges of the PWM signal to provide a controllable and distributed electromagnetic compatibility (EMC) signature for the device 100.

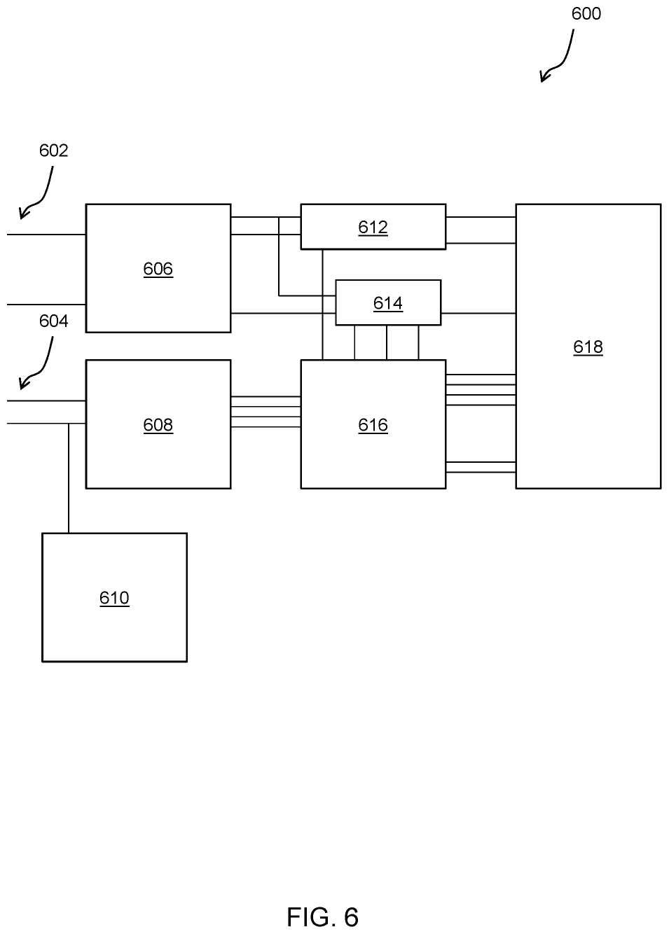

FIG. 6 is a diagram of an example vehicle headlamp system 600 that may incorporate one or more of the embodiments and examples described herein. The example vehicle headlamp system 600 illustrated in FIG. 6 includes power lines 602, a data bus 604, an input filter and protection module 606, a bus transceiver 608, a sensor module 610, an LED direct current to direct current (DC/DC) module 612, a logic low-dropout (LDO) module 614, a micro-controller 616, and an active head lamp 618.

The power lines 602 may have inputs that receive power from a vehicle, and the data bus 604 may have inputs/outputs over which data may be exchanged between the vehicle and the vehicle headlamp system 600. For example, the vehicle headlamp system 600 may receive instructions from other locations in the vehicle, such as instructions to turn on turn signaling or turn on headlamps, and may send feedback to other locations in the vehicle if desired. The sensor module 610 may be communicatively coupled to the data bus 604 and may provide additional data to the vehicle headlamp system 600 or other locations in the vehicle related to, for example, environmental conditions (e.g., time of day, rain, fog, or ambient light levels), vehicle state (e.g., parked, in-motion, speed of motion, or direction of motion), and presence/position of other objects (e.g., vehicles or pedestrians). A headlamp controller that is separate from any vehicle controller communicatively coupled to the vehicle data bus may also be included in the vehicle headlamp system 600. In FIG. 6, the headlamp controller may be a micro-controller, such as micro-controller (pc) 616. The micro-controller 616 may be communicatively coupled to the data bus 604.

The input filter and protection module 606 may be electrically coupled to the power lines 602 and may, for example, support various filters to reduce conducted emissions and provide power immunity. Additionally, the input filter and protection module 606 may provide electrostatic discharge (ESD) protection, load-dump protection, alternator field decay protection, and/or reverse polarity protection.

The LED DC/DC module 612 may be coupled between the input filter and protection module 106 and the active headlamp 618 to receive filtered power and provide a drive current to power LEDs in the LED array in the active headlamp 618. The LED DC/DC module 612 may have an input voltage between 6 and 18 volts with a nominal voltage of approximately 13.2 volts and an output voltage that may be slightly higher (e.g., 0.3 volts) than a maximum voltage for the LED array (e.g., as determined by factor or local calibration and operating condition adjustments due to load, temperature or other factors).

The logic LDO module 614 may be coupled to the input filter and protection module 606 to receive the filtered power. The logic LDO module 614 may also be coupled to the micro-controller 616 and the active headlamp 618 to provide power to the micro-controller 616 and/or electronics in the active headlamp 618, such as CMOS logic.

The bus transceiver 608 may have, for example, a universal asynchronous receiver transmitter (UART) or serial peripheral interface (SPI) interface and may be coupled to the micro-controller 616. The micro-controller 616 may translate vehicle input based on, or including, data from the sensor module 610. The translated vehicle input may include a video signal that is transferrable to an image buffer in the active headlamp 618. In addition, the micro-controller 616 may load default image frames and test for open/short pixels during startup. In embodiments, an SPI interface may load an image buffer in CMOS. Image frames may be full frame, differential or partial frames. Other features of micro-controller 616 may include control interface monitoring of CMOS status, including die temperature, as well as logic LDO output. In embodiments, LED DC/DC output may be dynamically controlled to minimize headroom. In addition to providing image frame data, other headlamp functions, such as complementary use in conjunction with side marker or turn signal lights, and/or activation of daytime running lights, may also be controlled.

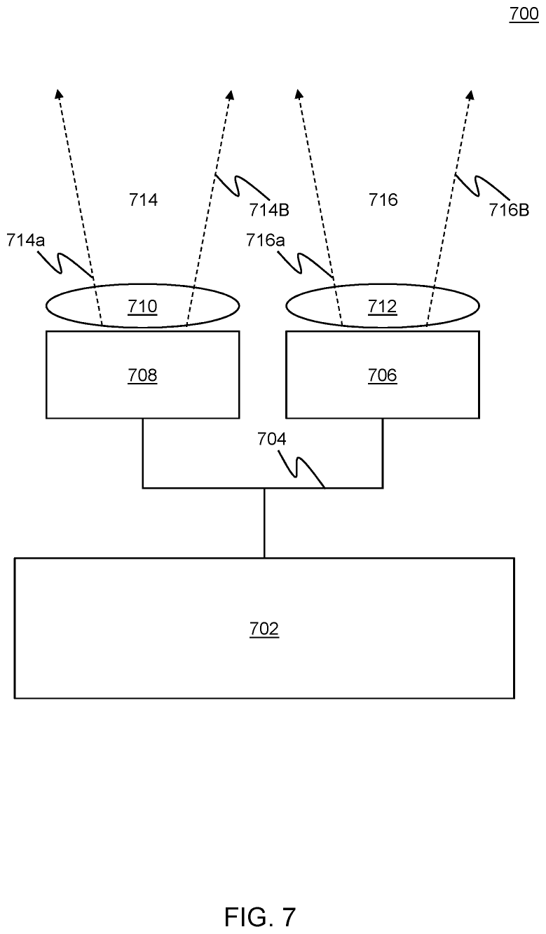

FIG. 7 is a diagram of another example vehicle headlamp system 700. The example vehicle headlamp system 700 illustrated in FIG. 7 includes an application platform 702, two LED lighting systems 706 and 708, and secondary optics 710 and 712.

The LED lighting system 708 may emit light beams 714 (shown between arrows 714a and 714b in FIG. 7). The LED lighting system 706 may emit light beams 716 (shown between arrows 716a and 716b in FIG. 7). In the embodiment shown in FIG. 7, a secondary optic 710 is adjacent the LED lighting system 708, and the light emitted from the LED lighting system 708 passes through the secondary optic 710. Similarly, a secondary optic 712 is adjacent the LED lighting system 706, and the light emitted from the LED lighting system 706 passes through the secondary optic 712. In alternative embodiments, no secondary optics 710/812 are provided in the vehicle headlamp system.

Where included, the secondary optics 710/812 may be or include one or more light guides. The one or more light guides may be edge lit or may have an interior opening that defines an interior edge of the light guide. LED lighting systems 708 and 706 may be inserted in the interior openings of the one or more light guides such that they inject light into the interior edge (interior opening light guide) or exterior edge (edge lit light guide) of the one or more light guides. In embodiments, the one or more light guides may shape the light emitted by the LED lighting systems 708 and 706 in a desired manner, such as, for example, with a gradient, a chamfered distribution, a narrow distribution, a wide distribution, or an angular distribution.

The application platform 702 may provide power and/or data to the LED lighting systems 706 and/or 708 via lines 704, which may include one or more or a portion of the power lines 602 and the data bus 604 of FIG. 6. One or more sensors (which may be the sensors in the vehicle headlamp system 700 or other additional sensors) may be internal or external to the housing of the application platform 702. Alternatively, or in addition, as shown in the example vehicle headlamp system 600 of FIG. 6, each LED lighting system 708 and 706 may include its own sensor module, connectivity and control module, power module, and/or LED array.

In embodiments, the vehicle headlamp system 700 may represent an automobile with steerable light beams where LEDs may be selectively activated to provide steerable light. For example, an array of LEDs or emitters may be used to define or project a shape or pattern or illuminate only selected sections of a roadway. In an example embodiment, infrared cameras or detector pixels within LED lighting systems 706 and 708 may be sensors (e.g., similar to sensors in the sensor module 610 of FIG. 6) that identify portions of a scene (e.g., roadway or pedestrian crossing) that require illumination.

As would be apparent to one skilled in the relevant art, based on the description herein, embodiments of the present invention can be designed in software using a hardware description language (HDL) such as, for example, Verilog or VHDL. The HDL-design can model the behavior of an electronic system, where the design can be synthesized and ultimately fabricated into a hardware device. In addition, the HDL-design can be stored in a computer product and loaded into a computer system prior to hardware manufacture.

Having described the embodiments in detail, those skilled in the art will appreciate that, given the present description, modifications may be made to the embodiments described herein without departing from the spirit of the inv concept. Therefore, it is not intended that the scope of the invention be limited to the specific embodiments illustrated and described.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

What is claimed is:

1. A device comprising:
a complementary metal-oxide semiconductor (CMOS) backplane comprising multiple light emitting diode (LED) pixels areas;
a plurality of pixel drivers inside the CMOS backplane, each pixel driver of the plurality of pixel drivers being coupled to a ground,
wherein one or more metal interconnect layers of the CMOS backplane configure the one or more pixel drivers into the one or more groups corresponding to the multiple LED pixels areas.

2. The device of claim 1, wherein the one or more metal interconnect layers comprise a full metal layer stack of the CMOS backplane configuring the one or more pixel drivers into the one or more groups.

3. The device of claim 1, wherein the one or more metal interconnect layers comprise a top layer that provides a shorting between the plurality of pixel drivers.

4. The device of claim 1, wherein the one or more groups comprise a same number of the plurality of pixel drivers.

5. The device of claim 1, wherein the one or more groups comprise varying numbers of the plurality of pixel drivers.

6. The device of claim 1, wherein a group of the one or more groups comprise four (4) pixel drivers of the plurality of pixel drivers.

7. The device of claim 1, wherein the device comprises a plurality of LEDs, and each area of the multiple LED pixels areas corresponds to an LED of the plurality of LEDs.

8. A device comprising:
a complementary metal-oxide semiconductor (CMOS) backplane comprising multiple light emitting diode (LED) pixels areas;
a plurality of pixel drivers inside the CMOS backplane, each pixel driver of the plurality of pixel drivers being coupled to a ground,
wherein the one or more pixel drivers are configured by an n-layer interconnect design into one or more groups corresponding to the multiple LED pixels areas.

9. The device of claim 8, wherein the device comprises a plurality of LEDs, and each area of the multiple LED pixels areas corresponds to an LED of the plurality of LEDs.

10. The device of claim 9, wherein each LED of the plurality of LEDs comprises the n-layer interconnect design that configures the one or more pixel drivers into the one or more groups corresponding to the multiple LED pixels areas.

11. The device of claim 10, wherein a die of each LED comprise the n-layer interconnect design and provides multiple n-contacts for each pixel driver of the one or more pixel drivers corresponding to a group of the one or more groups.

12. The device of claim 8, wherein the one or more groups comprise a same number of the plurality of pixel drivers.

13. The device of claim 8, wherein the one or more groups comprise varying numbers of the plurality of pixel drivers.

14. The device of claim 8, wherein a group of the one or more groups comprise four (4) pixel drivers of the plurality of pixel drivers.

15. A device comprising:
a complementary metal-oxide semiconductor (CMOS) backplane comprising multiple light emitting diode (LED) pixels areas;
a plurality of pixel drivers inside the CMOS backplane, each pixel driver of the plurality of pixel drivers being coupled to a ground,
wherein the one or more pixel drivers are configured into one or more groups corresponding to the multiple LED pixels areas.

16. The device of claim 15, wherein a hybrid configuration of the device configures the one or more pixel drivers into the one or more groups corresponding to the multiple LED pixels areas.

17. The device of claim 16, wherein the hybrid configuration comprises one or more metal interconnect layers of the CMOS backplane.

18. The device of claim 16, wherein the hybrid configuration comprises n-layer interconnect design.

19. The device of claim 15, wherein the device comprises a plurality of LEDs, and each area of the multiple LED pixels areas corresponds to an LED of the plurality of LEDs.

20. The device of claim 15, wherein a firmware of the CMOS digitally configure the one or more pixel drivers into the one or more groups to produce and route a combination of currents to corresponding to the multiple LED pixels areas.
